(19) United States
(12) Patent Application Publication
(10) Pub. No.: US 2005/0253744 A1
(43) Pub. Date: Nov. 17, 2005

(54) Configurable output circuit and method

(75) Inventor: Michael J. Kern, Milwaukee, WI (US)

Correspondence Address: FOLEY & LARDNER, 777 EAST WISCONSIN AVENUE, SUITE 3800, MILWAUKEE, WI, 53202-5308, US

(73) Assignee: Johnson Controls Technology Company

(21) Appl. No.: 10/844,955

(22) Filed: May 13, 2004

(51) Int. Cl. H03M 1/00

(52) U.S. Cl. 341/110

(57) ABSTRACT

A configurable output circuit is disclosed. The output circuit comprises an analog output circuit capable of producing an analog output signal usable to control the output device, a binary output circuit capable of producing a binary output signal usable to control the output device, and means for configuring the output circuit to provide an analog output mode or a binary output mode so that the output signal is either the binary output signal or the analog output signal. A method of providing an output control signal to an output device comprises providing an output circuit having a binary output circuit and an analog output circuit, receiving a first output mode control signal, configuring the output circuit in either a binary output mode or an analog output mode, receiving a first device control signal, and providing the output control signal to the output device as either a binary signal or an analog signal.

### FIELD

The present description relates generally to output circuits that provide output signals usable to control output devices. In particular, the present description relates to output circuits that are configurable to provide either an analog or binary output signal usable to control output devices.

### BACKGROUND

Output circuits are used for controlling output devices. In industrial applications, for example, output circuits are used to control devices such as fans, actuators, temperature control systems, lighting systems, and so on. One type of output circuit is an analog output circuit. Typically, analog output circuits provide a continuously varying output voltage or current having a magnitude which is indicative of a desired output state of an output device. For example, in some applications, industry standards have been developed which specify that such voltage output circuits provide an output voltage in the range of 0 to 10 volts, with the output voltage having a magnitude that is proportional to a desired output condition. Thus, for a variable speed motor, an output circuit may provide an output voltage having a magnitude of 5 volts to cause the motor to operate at 50% maximum speed. An output device that is controlled in this manner is often referred to as a voltage-controlled output device.

Another type of output circuit is binary output circuit. Typically, binary output circuits provide an output based on the base-two number system (i.e., in 1's and 0's) or another system wherein the output provided by the circuit has only two discrete levels (e.g., either 5 volts or 0 volts).

In general, an output device is either analog controlled output device or a binary controlled output device, but not both. Generally, it is necessary that the output circuit be matched with the type of output device used, that is, that analog output circuits be used with analog-controlled output devices and binary output circuits be used with binary-controlled output devices.

When installing a new control system or modifying an existing control system, it is not always known which type of output devices will be or have been used. For example, when modifying an existing control system, where a new controller is installed but the output devices of the original system remain in place, it is generally not known in advance whether particular output devices are analog output devices or binary output devices. While this information can be determined by examining product specifications for the output device and/or by performing suitable measurements, this process is time consuming and not always possible or practical to perform.

It is known to provide a circuit (e.g., in a device) that provides an analog or a binary output. It is also known to provide a circuit that provides both an analog and a binary output. However, such known circuits are “hardwired” and are not configured to be configurable, reconfigurable, adapted, changed, or the like. Once the circuit is manufactured or fabricated, the type of outputs cannot be altered or changed (e.g., between analog and binary). As such, an additional circuit or device would need to be provided if a different type of output is needed or desired (e.g., additional use or functionality is required upon or after installation).

Accordingly, it would be advantageous to provide a circuit that is adaptable. It would also be advantageous to provide an output that is configurable (or reconfigurable) before, during, or after installation (e.g., the electrical device is in the field). It would further be advantageous to provide an output that can be configured by software before, during or after installation. To provide an inexpensive, reliable, and widely adaptable configurable output that avoids the above-referenced and other problems would represent a significant advance in the art.

### SUMMARY

The present invention relates to a configurable output circuit capable of producing an output signal to control an output device. The output circuit comprises an analog output circuit capable of producing an analog output signal usable to control the output device, a binary output circuit capable of producing a binary output signal usable to control the output device, and means for configuring the output circuit to provide an analog output mode or a binary output mode so that the output signal is either the binary output signal or the analog output signal.

The present invention also relates to a system comprising a controller, an output device, an output circuit configurable in an analog output mode wherein an analog output circuit portion of the output circuit is capable of producing an analog output signal usable to control the output device, and a binary output mode wherein a binary output circuit portion of the output circuit is capable of producing a binary output signal usable to control the output device.

The present invention further relates to a configurable output circuit capable of producing an output signal. The output circuit comprises a first input configured to receive a first input signal, a first output circuit being capable of producing an analog output signal based on the first input signal and usable to control an output device, a second output circuit being capable of producing a binary output signal based on the first input signal and usable to control the output device, a second input configured to receive a second input signal, and a switch being capable of switching the output signal between a first mode of operation in which the first output circuit is active to a second mode of operation in which the second output circuit is active, the switch switching the configurable output circuit between the first mode of operation and the second mode of operation responsive to the second input signal.

The present invention further relates to a method of providing an output control signal to an output device. The method comprises providing an output circuit having a binary output circuit and an analog output circuit, receiving a first output mode control signal, configuring the output circuit in either a binary output mode or an analog output mode, receiving a first device control signal, and providing the output control signal to the output device as either a binary signal or an analog signal.

The present invention further relates to various features and combinations of features shown and described in the disclosed embodiments.

### DESCRIPTION OF THE FIGURES

FIG. 1 is a block diagram illustrating a control system that includes a configurable output circuit according to an exemplary embodiment.

FIG. 2 schematically illustrates the configurable output circuit of FIG. 1 according to a first exemplary embodiment.

FIG. 3 schematically illustrates the analog output portion of the configurable output circuit of FIG. 2 according to an exemplary embodiment.

FIG. 4 schematically illustrates the binary output portion of the configurable output circuit of FIG. 2 according to an exemplary embodiment.

FIG. 5 schematically illustrates the configurable output circuit of FIG. 1 according to a second exemplary embodiment.

FIG. 6 schematically illustrates the configurable output circuit of FIG. 1 according to a third exemplary embodiment.

FIG. 7 is a block diagram illustrating a control system that includes a configurable output circuit according to an alternative embodiment.

FIG. 8 schematically illustrates the configurable output circuit of FIG. 7 according to a first exemplary embodiment.

FIG. 9 schematically illustrates the analog output portion of the configurable output circuit of FIG. 8 according to an exemplary embodiment.

FIG. 10 schematically illustrates the binary output portion of the configurable output circuit of FIG. 8 according to an exemplary embodiment.

### DETAILED DESCRIPTION

The configurable output design is adaptable for any of a variety of controlled systems or applications, including office, home, manufacturing, industrial, commercial or other systems that employ a controller output. For purposes of explanation, the components of the disclosed embodiments will be illustrated as a configurable output designed for an industrial control application, such as a heating, ventilation, and air-conditioning (HVAC) system, the features of the disclosed embodiments have a much wider applicability.

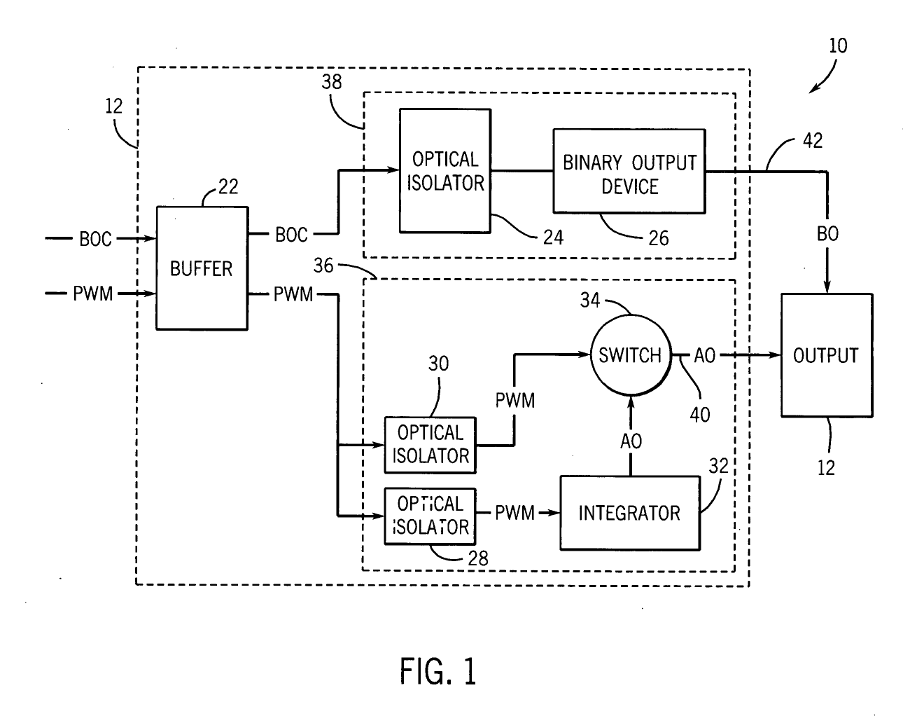

FIG. 1 illustrates a block diagram of a control system 10 including a configurable output circuit 20 according to an exemplary embodiment. Control system 10 may be any type of control system. For example, in one embodiment, control system 10 is an industrial control system such as a heating, ventilating, and air-conditioning (HVAC) system. Control system 10 includes an output system or device 12, a pulse width modulated (PWM) signal 16, and a binary output control (BOC) signal 18 to output circuit 20.

Output system or device 12 is coupled to output circuit 20. Output system or device 12 may be a lighting system, a mechanical actuator, a fan, a temperature control system, or any other type of output device. In one embodiment, output system or device 12 is configured to accept an analog output signal 40 from output circuit 20. In another embodiment, output system or device 12 is configured to accept a binary output signal 42 from output circuit 20.

PWM signal 16 is, for example, a time-optimized PWM signal provided by system 10 to generate an analog output signal. BOC signal 18 is provided by system 10 (e.g., from a system controller configured to control output system or device 12) as a control signal which is the basis for a binary output signal to be provided to output system or device 12. For example, in one embodiment BOC signal 18 is set to either a 0 volt level or a 5 volt level which output circuit 10 processes into a binary output signal. BOC signal 18 may be generated by any of a variety of controllers, such as a microprocessor-based controller, the output of an A/D or D/A converter, the output of a potentiometer, or the like.

Output circuit 20 is configured to be coupled to output system or device 12, and may be incorporated into system 10 in a number of ways. For example, output circuit 20 may be may be included in any of a variety of electrical or electronic apparatuses or subsystems used within system 10. In one embodiment, an electronic controller within system 10 includes one or more configurable output circuits 20. In another embodiment, the controller is configured to provide one or more fixed (or “hard-wired”) outputs and one or more output circuits 20. Such devices (with configurable outputs) are intended to be more flexible during installation (e.g., connectable to systems or devices not known when the device was manufactured; to provide future adaptability to add or change systems or devices connected to the device; or the like).

Output circuit 20 includes a buffer 22, an optical isolator 24, a binary output device 26, optical isolators 28 and 30, an integrator 32, and a switch 34. Output circuit 20 receives PWM signal 16, and BOC signal 18 as inputs. Output circuit 20 is subdivided into an analog output circuit 36 and a binary output circuit 38. Output circuit 20 is capable of being configured (e.g., using software during installation or during a later modification) to provide an analog output mode or a binary output mode depending on the type or characteristics of output system or device 12. In the analog output mode of operation, output circuit 20 provides an analog output signal 40 to output system or device 12. In the binary output mode of operation, output circuit 20 provides a binary output signal 42 to output system or device 12.

Buffer 22 is configured to receive PWM signal 16, and BOC signal 18 as inputs. Buffer 22 is further configured to isolate the sources (not shown) of PWM signal 16, and BOC signal 18 by, for example, minimizing impedance effects from output circuit 10.

Optical isolator 24, included in binary output circuit 38, is coupled to buffer 22 and to binary output device 26 and is configured to receive BOC signal 18 from buffer 22. Optical isolator 24 is a transistor or other suitable electronic switching device. Optical isolator 24 operates to apply BOC signal 18 to binary output device 26.

Binary output device 26, included in binary output circuit 38, is coupled to optical isolator 24 and output system or device 12. Binary output device 26 is configured to receive BOC signal 18 from optical isolator 24 and to provide binary output signal 42 to output system or device 12 in response to BOC signal 18. Binary output device 26 is also configured to optically isolate output system or device 12 from the source of each input (not shown) to output circuit 20 to, for example, prevent electrical damage to each source. For example, in one embodiment, output system or device 12 is an alternating current (AC) device, and binary output device 26 is configured to switch an AC power source according to BOC signal 18 while optically isolating the source of BOC signal 18 from the AC power source.

Optical isolators 28 and 30, included in analog output circuit 36, are coupled to buffer 22. Optical isolators 28 and 30 are further coupled to integrator 32 and are configured to receive PWM signal 16 from buffer 22 and to provide PWM signal 16 to integrator 32. Optical isolators 28 and 30 are also configured to optically isolate output system or device 12 from the source of each input (not shown) to output circuit 20 to, for example, prevent electrical damage to each source.

Integrator 32, included in analog output circuit 36, is coupled to optical isolators 28 and 30, and to switch 34. Integrator 32 is configured to receive PWM signal 16 from optical isolators 28 and 30, and to provide an analog output signal 40 to switch 34 that is based on PWM signal 16 as received from optical isolators 28 and 30.

Switch 34, included in analog output circuit 36, is coupled to optical isolators 28 and 30, integrator 32, and output system or device 12. Switch 34 is configured to receive analog output signal 40 from integrator 32, as well as PWM signal 16 from optical isolators 28 and 30, and to provide analog output signal 40 to output system or device 12 in response to PWM signal 16.

Output circuit 20 is configured to receive PWM signal 16 and BOC signal 18, and to processes PWM signal 16 and BOC signal 18 according to the configuration of output circuit 20. Output circuit 20 then provides the processed output signal to output device 12. Depending on the configuration of output circuit 20 as determined by PWM signal 16 and BOC signal 18, output circuit 20 provides an analog output signal 40 using analog output circuitry 36, or a binary output signal 42 using binary output control circuitry 38. For example, according to an exemplary embodiment, output circuit 20 may be configured to operate in analog output mode by varying PWM signal 16 from 0 percent to 100 percent and setting BOC signal 18 to 0 volts. When output circuit 20 is configured to operate in analog output mode, optical isolator 24 is “OFF” according to BOC signal 18, and PWM signal 16 is received by optical isolators 28 and 30. Optical isolators 28 and 30 provide PWM signal 16 to integrator 32, which then provides analog output signal 40 based on PWM signal 16 to switch 34. Switch 34 is “ON” according to PWM signal 16, and provides analog output signal 40 to output system or device 12.

Continuing with the embodiment, output circuit 20 may be configured to operate in binary output mode by setting PWM signal to 0 percent and switching BOC signal 18 from 0 volts to 5 volts. When output circuit 20 is configured to operate in binary mode, BOC signal 18 is received by switch 24, which is “ON” while switch 34 is “OFF” according to PWM signal 16. Optical isolator 24 then provides a signal to binary output device 26, which provides binary output signal 42 to output system or device 12.

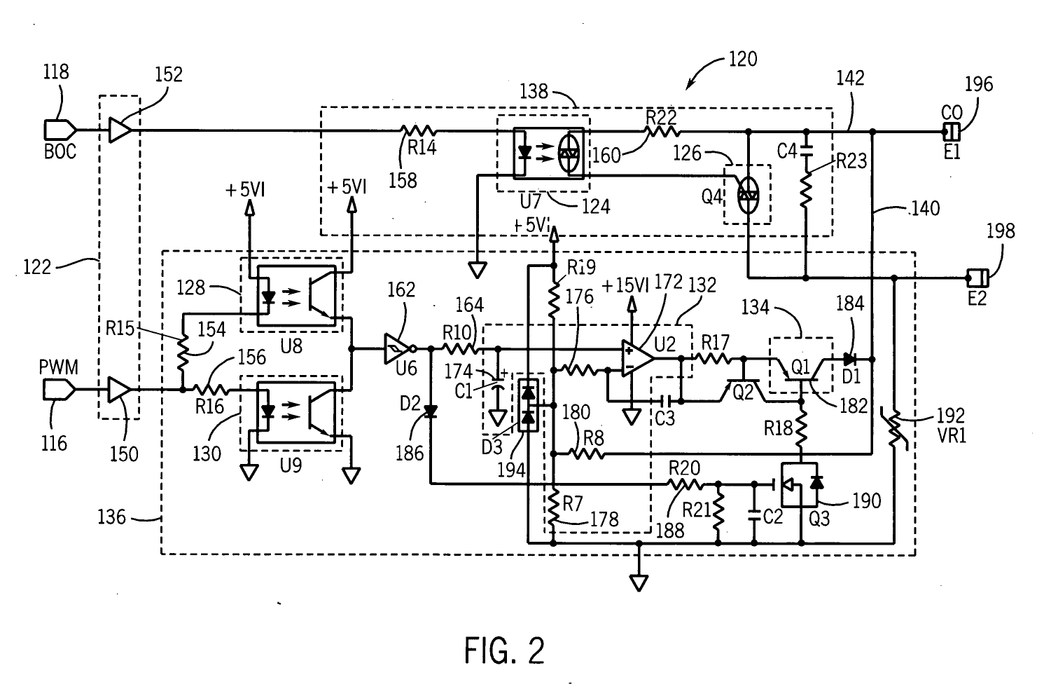

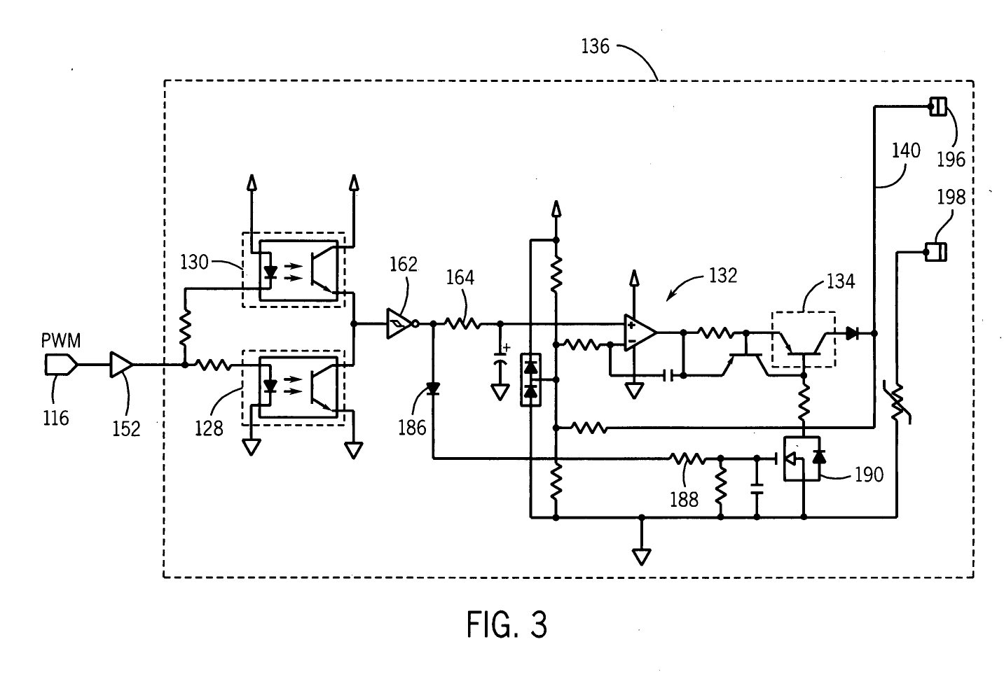

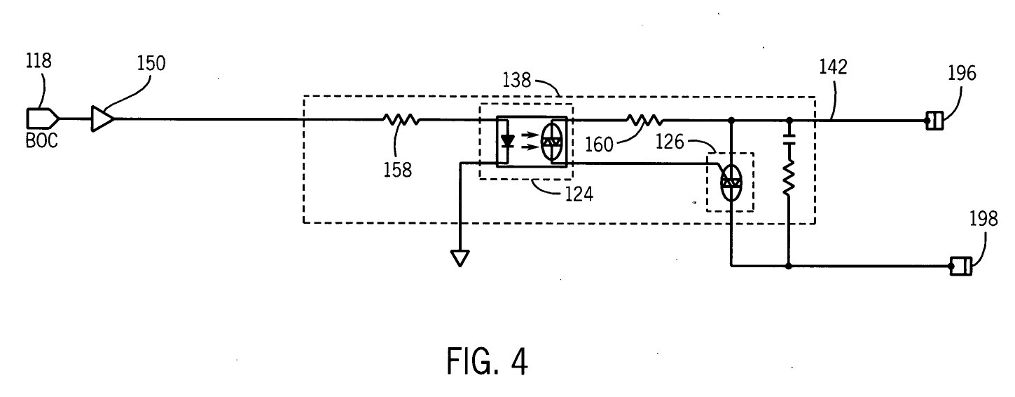

FIG. 2 schematically illustrates a configurable output circuit 120 which is an embodiment of output circuit 20 shown in FIG. 1. Output circuit 120 receives PWM signal 116, and BOC signal 118 as inputs, and includes a buffer 122, an optical isolator 124, a binary output device in the form of a triac 126, optical isolators 128 and 130, an integrator 132, and a switch 134. Output circuit 120 is subdivided into an analog output circuit 136 (shown in FIG. 3) and a binary output circuit 138 (shown in FIG. 4). In analog output mode, analog output circuit 136 provides analog output signal 140. In binary output mode, binary output circuit 138 provides binary output signal 142.

Table I below provides exemplary input and output signal ratings for output circuit 120.

| Symbol | Parameter | Value | Units |
|---|---|---|---|
| PWM | Pulse Width Modulated (PWM) Input Signal | | |
| | Maximum Frequency | 1000 | Hz |
| | Minimum Input Signal | 3.15 | V |
| BOC | Binary Output Control Signal | | |
| | Minimum Input High Level | 3.51 | V |
| CO | Configurable Output | | |
| | Maximum Output Voltage: analog output, binary output | 10, ±36 | V |
| | Maximum Output: analog output, binary output | 10, 500 | mA |
| | Maximum Surge Current (binary output 10us) | 5 | A |
| | Maximum Blocking Voltage (binary output) | 400 | V |
| 15 VI | 15 V Isolated Power Supply | 14.25 to | V |
| | | 15.75 | |
| 5 VI | 5 VI Isolated Power Supply (5 VI isolated power supply | 4.75 to | V |
| | derived from 15 VI using voltage reference) | 5.05 | |
| Power | Maximum Power Dissipation: | | |
| Dissipation | Analog Output | 735 | mW |
| | Binary Output | 1961 | mW |

Table II below provides exemplary component values for output circuit 120.

| | Component | |
|---|---|---|
| Qty | Reference | Description |
| 1 | U5 | TL431 |
| 1 | C1 | ELEC, 2.2 UF, 50 V, TA, 20%, −40 + 85 |
| 1 | C2 | Mult. Cer. SMD Cap. 2,2 nF 50 V 0805 X7R 10% |
| 1 | C3 | Capacitor, Ceramic Disc, 0.01 uF, 20%, 500 V, −55 + 105, Crimped |
| | | Leads |
| 1 | C4 | CAP., POLYP, .01UF, 100 V, RADIAL, 10%, −40 + 100 |
| 2 | D1-D2 | DIODE, 75 V 200 mA, BAS16 SOT23 |
| 1 | D3 | DIODE, DUAL DIODE, LOW POWER |
| 2 | E1,E2 | TERM, FASTON, 0.250 TAB SIZE |
| 2 | Q1-Q2 | MMBTA56, DRIVER, PNP, S3 |
| 1 | Q3 | MOSFET_N-Channel_60 V_115 mA_2N7002_SOT23 |
| 1 | Q4 | TRIAC, Q4004F42 4 A 400 V TO220 |
| 1 | R14 | RES, 340 OHM, 1%, 1/8 W 200 PPM |
| 2 | R15-R16 | RES, MF, 1.54 K, 1 %, .125 W, TA, 100 PPM, AS0017 |
| 1 | R17 | RES, THK, 47, 1%, .062 W, S2, THK, 100 PPM |
| 2 | R18-R19 | RES, 10 K, 1% .0625W, THK 100 PPM |
| 1 | R20 | RES, 3.32 K, 1% .0625W, THK 100 PPM |
| 1 | R21 | RES, 1.54 K OHM, 1%, 1/16 W 100 PPM |
| 1 | R22 | RES, 75 OHM, 5%, 1/2 W 200 PPM |
| 1 | R23 | RES, CF, 47, 5%, .5 W, TA, #PPM |
| 1 | R7 | R, 75.OK, 1%, .062 W, S2, THK, 100 PPM |
| 2 | R8,R10 | RES, 100 K, 1%, 1/16 W 100 PPM |
| 1 | R9 | RES, 47.5 K, 1% .0625 W, THK 100 PPM |
| 1 | U2 | IC_OperationalAmplifier_Quad_LM2902_SO14 |
| 1 | U6 | IC, DIGITAL, 74AHC1G14, SCHMITT TRIGGER INVERTER, SINGLE |
| | | GATE, CMOS, SMT, SOT23-5 |
| 1 | U7 | IC, OptoCoupler, TLP16OG |
| 2 | U8-U9 | IC, OPTOISOLATOR, HCPL-181, 4 PIN SMT PKG |
| 1 | VR1 | PTC, 10, 24 V, 320 mA, TR |

Buffer 122 includes buffers 150 and 152. In one embodiment, buffers 150 and 152 are part of a single integrated circuit (IC) package. In another embodiment, buffers 150 and 152 are separate ICs. Buffer 150 receives PWM signal 116 as an input. Buffer 150 is coupled to optical isolator 128 via resistor 154, and to optical isolator 130 via resistor 156 such that optical isolators 128 and 130 receive PWM signal 116 as an input. Buffer 152 receives BOC signal 118 as an input. Buffer 152 is coupled to optical isolator 124 via resistor 158 such that optical isolator 124 receives BOC signal 118 as an input.

The anode of optical isolator 124 is coupled to buffer 152 via resistor 158 such that it receives BOC signal 118, while the cathode of optical isolator 124 is coupled to ground. MT1 of optical isolator 124 is coupled to triac 126 via resistor 160 and MT2 of optical isolator 124 is directly coupled to the gate of triac 126. In the illustrated embodiment, optical isolator 124 is an optically isolated switch. In this embodiment an optically isolated switch is used in order to isolate BOC signal 118 from an AC output device (not shown) coupled to output circuit 20 without the slow speed and short life of the contacts associated with mechanical relays.

Triac 126, included in binary output circuit 138, is configured to receive BOC signal 118 from optical isolator 124 and to provide binary output signal 142 to an output system or device (not shown) coupled to output terminals 196 and 198 in response to BOC signal 118. In the illustrated embodiment, triac 126 is optically controlled by optical isolator 124.

Optical isolator 128, included in analog output circuit 136, is coupled to buffer 150 via resistor 154 such that it receives PWM signal 116 as an input. Optical isolator 128 is further coupled to integrator 132 via buffer 162 and resistor 164 such that it provides inverted PWM signal 116 to integrator 132. Optical isolator 130, included in analog output circuit 136, is coupled to buffer 150 via resistor 156 such that it receives PWM signal 116 as an input. Optical isolator 130 is further coupled to integrator 132 via buffer 162 and resistor 164 such that it provides inverted PWM signal 116 to integrator 132.

Integrator 132, included in analog output circuit 136, includes operational amplifier 172, capacitor 174, and resistors 176, 178, and 180. In the illustrated embodiment, capacitor 174 and resistors 176, 178, and 180 are selected such that integrator 132 has a time constant of about 1.045 seconds. In another embodiment, other values may be selected. Integrator 132 is coupled to optical isolator 128 via buffer 162 and resistor 164 such that it receives inverted PWM signal 116 as an input to non-inverting input of operational amplifier 172. Integrator 132 is further coupled to switch 134 and is configured to provide a time averaged version of inverted PWM signal 116 to switch 134 in the form of analog output signal 140.

Switch 134, included in analog output circuit 136, includes transistor 182. The drain of transistor 182 is coupled to integrator 132 such that it receives analog output signal 140 from integrator 140. The source of transistor 182 is coupled to output terminal 196 and to integrator 132 via diode 184 such that switch 134 provides analog output signal 140 to an output system or device (not shown) coupled to output terminals 196 and 198, as well as to integrator 132 as a feedback signal. The gate of transistor 182 receives inverted PWM signal 116 as an input via diode 186, resistor 188, and transistor 190.

FIG. 3 schematically illustrates a simplified version of output circuit 120 in which the circuit components that are not used in analog output mode have been removed and the components of analog output circuit 136 are shown. Analog output circuit 136 receives PWM signal 116 from buffer 152 and includes optical isolators 128 and 130, integrator 132, and switch 134. When output circuit 120 operates in analog output mode, analog output circuit 136 provides analog output signal 140 to an output system or device (not shown) coupled to output terminals 196 and 198.

In the illustrated embodiment, in order to configure output circuit 120 to operate in analog output mode, BOC signal 118 (not shown) is set to a TTL “low.” PWM signal 116 is received by optical isolators 128 and 130. PWM signal 116 is also coupled to diode 186 via buffer 162, such that it is inverted. The gate of transistor 190 is coupled to diode 186 via resistor 188. When PWM signal 116 is a TTL “low,” transistor 190 is “ON.” Accordingly, switch 134 provides analog output signal 140 to an output system or device (not shown) coupled to output terminals 196 and 198.

According to an exemplary embodiment, PWM signal 116 is a time-optimized pulse width modulated signal that is used to generate analog output signal 140. When output circuit 120 is configured to operate in analog output mode, PWM signal 116 is received by optical isolators 128 and 130. Optical isolators 128 and 130 couple PWM signal 116 to integrator 132 via buffer 162 and resistor 164. Integrator 132 then provides analog output signal 140 to switch 134, which provides analog output signal 140 to an output system or device (not shown) coupled to output terminals 196 and 198.

FIG. 4 schematically illustrates a simplified version of output circuit 120 in which the circuit components that are not used in binary output mode have been removed and the components of binary output circuit 138 are shown. Binary output circuit 138 receives BOC signal 118 from buffer 150 and includes optical isolator 124 and triac 126. When output circuit 120 operates in binary output mode, binary output circuit 138 provides binary output signal 142 to an output system or device (not shown) coupled to output terminals 196 and 198. In binary mode, BOC signal 118 is used to provide current to the optically controlled driver of triac 126, which in turn provides gate current to triac 126.

In order to configure output circuit 120 to operate in binary output mode, PWM signal 116 (not shown) is set to 0 percent modulation. BOC signal 118 is set to TTL “high” and is coupled to the anode of optical isolator 124 through resistor 158. Optical isolator 124 is “ON” and accordingly couples BOC signal 118 to triac 126 via resistor 160 such that triac 126 is opened and closed according to BOC signal 118 to provide binary output signal 142 to an output system or device (not shown) coupled to output terminals 196 and 198.

According to the illustrated embodiment, analog output circuit 136 and binary output circuit 138 share output terminals 196 and 198. Analog output circuit 136 is protected from high voltage spikes when output circuit 120 is configured to operate in binary output mode by voltage regulating device 192. Further, the inputs to operational amplifier 172 are protected when the device is in binary output mode by dual diode 194. Dual diode 194 limits the voltage at the input of operational amplifier 172 by clamping it to the 5 volt supply.

In typical applications and installations (e.g., an electrical device in a controlled system), electrical devices using output device 10 are installed (e.g., mounting and wiring of the electrical device(s)) and configured (e.g., initiation, powering-up, programming, testing, etc.) by different persons (e.g., having different expertise and/or negotiated responsibilities). For example, in a new construction installation, a first person (such as an electrician) mounts or installs the device and connects the wiring. Thereafter, a second person (such as a building, systems, or HVAC engineer) can program, reprogram, initiate, power-up or otherwise have operational control over HVAC system.

The device with the configurable output may be a general device configured for a variety of applications and systems, which would have an unknown input characteristic (e.g., analog or binary). This general device may be configured according to the application. Alternatively, while the system is being configured, tested, and/or powered-up, it may become desirable to add an additional controlled device. If necessary, the configurable output can be configured to be compatible with this additional controlled device. Alternatively, after the installation and initial configuration, it may become desirable to modify or expand the controlled system. Such modification may require a different output. An engineer or other technician can configure the output accordingly.

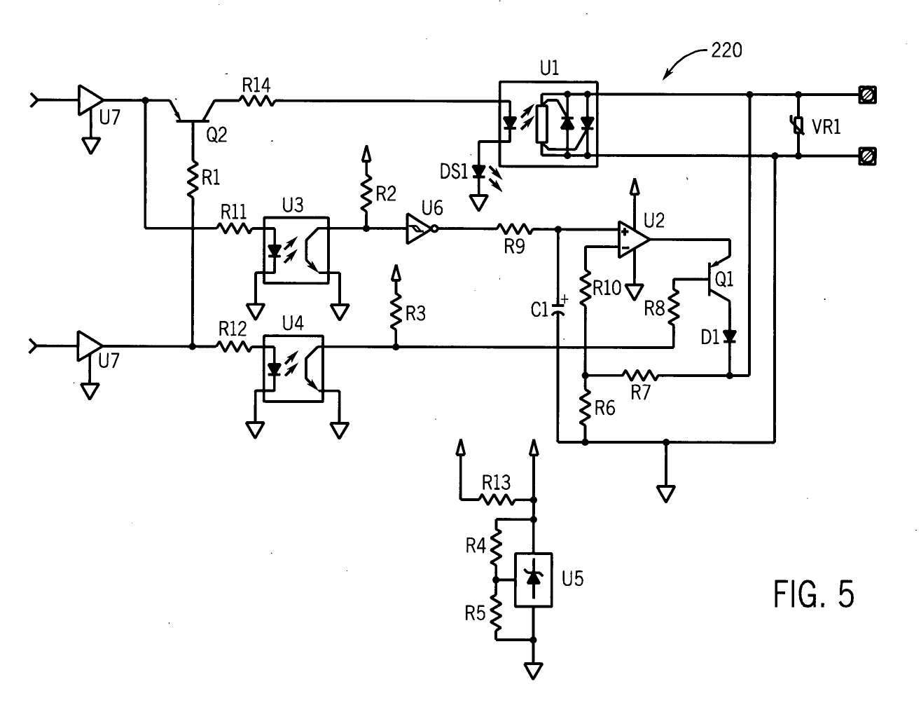

FIG. 5 schematically illustrates a configurable output circuit 220 according to another exemplary embodiment. Table III below provides exemplary values for the circuit of FIG. 5.

| Component | | |
|---|---|---|
| Reference | Quantity | Description |
| U1 | 1 | IC, OPTO ISOLATOR, SP646 SCR |
| R11-R12 | 2 | RES, 281 OHM, 1%, 1/16 W 200 PPM |
| C1 | 1 | ELEC, 22 UF, 16 V, TR, 20%,‘40 + 105 |
| J1 | 1 | S-BLOCK, 1 × 10, OMIS, FS, SCREW TERMINAL |
| VR1 | 1 | MOV, 68 V, 56 V, 100 A, TR |
| U3-U4 | 2 | IC, OptoCoupler, TLP621 |
| Q1-Q2 | 2 | MMBTA56, DRIVER, PNP, S3 |
| U2 | 1 | IC_OperationalAmplifier_Quad_LM2902_SO14 |
| U5 | 1 | IC, VOLTAGE REF. TL431 |
| U7 | 1 | IC<Digital. TriState-Quad Buffer, CMOS, SO14, MC74HC125AD |
| D1 | 1 | Diode, Switching, 100 V, 25 nA, 225 mW, 1N4148, SOT23 |
| R14 | 1 | RES, 499 OHM, 1%, 1/8 W 200 PPM |
| DS1 | 1 | LED_Red_Diffused_2.6 mcd @ 20 mA_155_1206 |
| R1-R8 | 8 | RES, 10 K, 1% .0625 W, THK 100 PPM |
| R9-R10 | 2 | RES, 47.5 K, 1% .0625 W, THK 100 PPM |
| R13 | 1 | RES, 4.99 K OHM, 1%, 1/16 W 200 PPM |
| U6 | 1 | IC, DIGITAL, 74AHC1G14, SCHMITT TRIGGER INVERTER, |
| | | SINGLE GATE, CMOS, SMT; SOT23- |

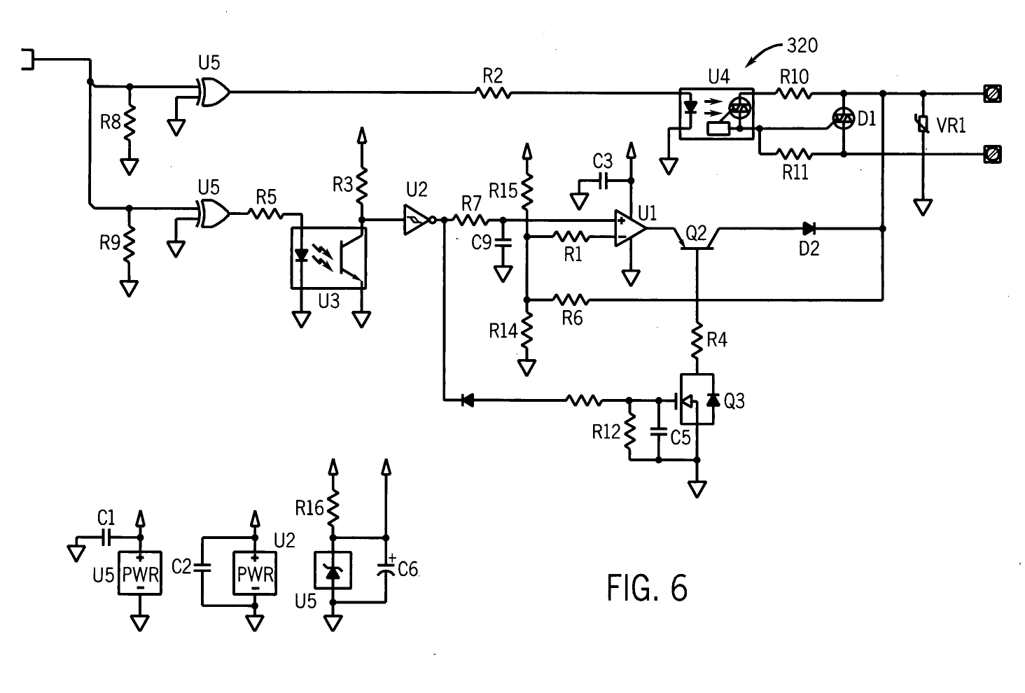

FIG. 6 schematically illustrates a configurable output circuit 320 according to an exemplary embodiment. Output circuit 320 differs from output circuit 120 (shown in FIG. 2) in that output circuit 320 is self-configuring. Output circuit 320 receives a single PWM input signal that is either a PWM signal for a binary output or a PWM signal for an analog output. Output circuit 320 selects binary output mode if a PWM signal for a binary output is received, or analog output mode if a PWM signal for an analog output is received.

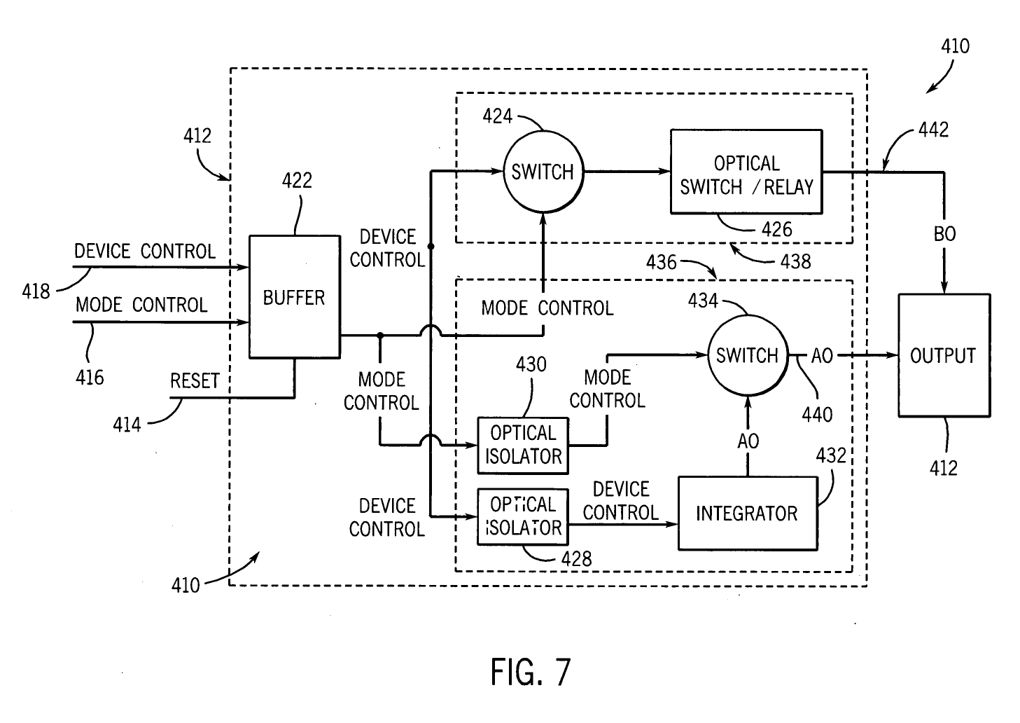

FIG. 7 illustrates a block diagram of a control system 410 including a configurable output circuit 420 according to an exemplary embodiment. Control system 410 may be any type of control system. For example, in one embodiment, control system 410 is an industrial control system such as a heating, ventilating, and air-conditioning (HVAC) system. Control system 410 includes an output system or device 412, and provides a reset signal 414, a mode control signal 416, and a device control signal 418 to output circuit 420.

Output system or device 412 is coupled to output circuit 420. Output system or device 412 may be a lighting system, a mechanical actuator, a fan, a temperature control system, or any other type of output device. Output system or device 414 may also be a microprocessor-based system that accepts the output signal from output circuit 410 as an input signal, digitizes the input signal, and uses the input signal for microprocessor-based control of output device 414. As another example, output device 414 may be an electromechanical actuator that has a state which is directly controlled by the signal from the output circuit 410. In one embodiment, output system or device 412 is configured to accept an analog output signal 440 from output circuit 420. In another embodiment, output system or device 412 is configured to accept a binary output signal 442 from output circuit 420.

Reset signal 414 is provided by system 410 (e.g., from a computer or other device capable of configuring or reconfiguring output control circuit 420) to set mode control signal 416 and device control signal 418 to known states during, for example, a system reset. Mode control signal 416 is provided by system 410 to configure (or reconfigure) output circuit 420 to operate in an analog output mode or in a binary output mode. For example, in one embodiment, mode control signal 416 is a transistor-transistor logic (TTL) signal which provides a TTL “high” signal to configure output circuit 420 to operate in analog output mode, or a TTL “low” signal to configure output circuit 420 to operate in binary mode. Mode control signal 416 may be provided by system 410 to output circuit 420 in a variety of ways. In one embodiment, mode control signal 416 is provided by an operator using software. In another embodiment, mode control signal 416 is provided by any of a variety of inputs, such as computing device (e.g., a laptop, personal digital assistant (PDA), etc. that may be permanently or temporarily coupled to the output circuit 420), or the like. According to another embodiment, mode control signal 416 is set or configured during installation. In another embodiment, mode control signal 416 is configured (or reconfigured or modified) after installation. In one embodiment, configuring (or reconfiguring) of mode control signal 416 is done by an operator (e.g., technician, engineer, etc.). In another embodiment, configuring (or reconfiguring) is done by another system in communication with output circuit 420.

Device control signal 418 is provided by system 410 (e.g., from a system controller configured to control output system or device 412) as a control signal which is the basis for either a binary or analog output signal to be provided to output system or device 412. For example, in one embodiment device control signal 418 is pulse width modulated (PWM) signal which output circuit 410 processes into either an analog output signal or a binary output signal. Device control signal 418 provides a control signal which is the basis for either analog output signal 440 or binary output signal 442. Device control signal 418 may be generated by any of a variety of controllers, such as a microprocessor-based controller, the output of an A/D or D/A converter, the output of a potentiometer, or the like.

Output circuit 420 is configured to be coupled to output system or device 412, and may be incorporated into system 410 in a number of ways. For example, output circuit 420 may be may be included in any of a variety of electrical or electronic apparatuses or subsystems used within system 410. In one embodiment, an electronic controller within system 410 includes one or more configurable output circuits 420. In another embodiment, the controller is configured to provide one or more fixed (or “hard-wired”) outputs and one or more output circuits 420. Such devices (with configurable outputs) are intended to be more flexible during installation (e.g., connectable to systems or devices not known when device 412 was manufactured; to provide future adaptability to add or change systems or devices connected to device 412; or the like).

Output circuit 420 includes a buffer 422, a switch 424, an optical switch/relay 426, optical isolators 428 and 430, an integrator 432, and a switch 434. Output circuit 420 receives reset signal 414, mode control signal 416, and device control signal 418 as inputs. Output circuit 420 is subdivided into an analog output circuit 436 and a binary output circuit 438. Output circuit 420 is capable of being configured (e.g., using software during installation or during a later modification) to provide an analog output mode or a binary output mode depending on the type or characteristics of output system or device 412. In the analog output mode of operation, output circuit 420 provides an analog output signal 440 to output system or device 412. In the binary output mode of operation, output circuit 420 provides a binary output signal 442 to output system or device 412.

Buffer 422 is configured to receive reset signal 414, mode control signal 416, and device control signal 418 as inputs. Buffer 422 is further configured to isolate the sources (not shown) of reset signal 414, mode control signal 416, and output device control signal 418 by, for example, minimizing impedance effects from output circuit 10. Buffer 422 is also configured to allow reset signal 414 to set mode control signal 416 and device control signal 418 to a known state during, for example, a system reset.

Switch 424, included in binary output circuit 438, is coupled to buffer 422 and to optical switch/relay 426 and is configured to receive mode control signal 416 and device control signal 418 from buffer 422. Switch 424 is a transistor or other suitable electronic switching device. Switch 424 operates to couple device control signal 418 to optical switch/relay 426 in response to output mode control signal 426.

Optical switch/relay 426, included in binary output circuit 438, is coupled to switch 424 and output system or device 412. Optical switch/relay 426 is configured to receive device control signal 418 from switch 424 and to provide binary output signal 442 to output system or device 412 in response to device control signal 418. Optical switch/relay is also configured to optically isolate output system or device 412 from the source of each input (not shown) to output circuit 420 to, for example, prevent electrical damage to each source. For example, in one embodiment, output system or device 412 is an alternating current (AC) device, and optical switch/relay 420 is configured to switch an AC power source according to device control signal 418 (e.g., a PWM signal) while optically isolating the source of device control signal 418 from the AC power source.

Optical isolators 428 and 430, included in analog output circuit 436, are coupled to buffer 422. Optical isolator 428 is further coupled to integrator 432 and is configured to receive device control signal 418 from buffer 422 and to provide device control signal 418 to integrator 432. Optical isolator 428 is also configured to optically isolate output system or device 412 from the source of each input (not shown) to output circuit 420 to, for example, prevent electrical damage to each source. Optical isolator 430 is further coupled to switch 434 and is configured to receive mode control signal 416 from buffer 422 and to provide mode control signal 416 to switch 434. Optical isolator 430 is also configured to optically isolate output system or device 412 from the source of each input (not shown) to output circuit 420 to, for example, prevent damage electrical damage to each source.

Integrator 432, included in analog output circuit 436, is coupled to optical isolator 428 and to switch 434. Integrator 432 is configured to receive device control signal 418 from optical isolator 428 and to provide an analog output signal 440 to switch 434 that is based on device control signal 418 as received from optical isolator 428.

Switch 434, included in analog output circuit 436, is coupled to optical isolator 430, integrator 432, and output system or device 412. Switch 424 is a transistor or other suitable electronic switching device. Switch 434 is configured to receive analog output signal 440 from integrator 432, as well as mode control signal 416 from optical isolator 430, and to provide analog output signal 440 to output system or device 412 in response to mode control signal 426.

Output circuit 420 is configured to receive mode control signal 416 and device control signal 418, and to processes device control signal 418 according to the configuration of output circuit 420 indicated by mode control signal 416. Output circuit 420 then provides the processed output signal to output device 412. Depending on the configuration of output circuit 420 as determined by mode control signal 416, device control signal 418 is processed as an analog output signal 440 using analog output circuitry 30, or a binary output signal 442 using binary output control circuitry 432. For example, where output circuit 420 is configured to operate in analog output mode, switch 424 is “OFF” according to mode control signal 416, and device control signal 418 is received by optical isolator 428. Optical isolator 428 provides device control signal 418 to integrator 432, which then provides analog output signal 440 based on control signal 418 to switch 434. Switch 434 is “ON” according to mode control signal 416, and provides analog output signal 440 to output system or device 412. Where output circuit 420 is configured to operate in binary mode, device control signal 418 is received by switch 424, which is “ON” while switch 434 is “OFF” according to mode control signal 416. Switch 424 then provides a signal to optical switch/relay 426, which provides binary output signal 442 to output system or device 412.

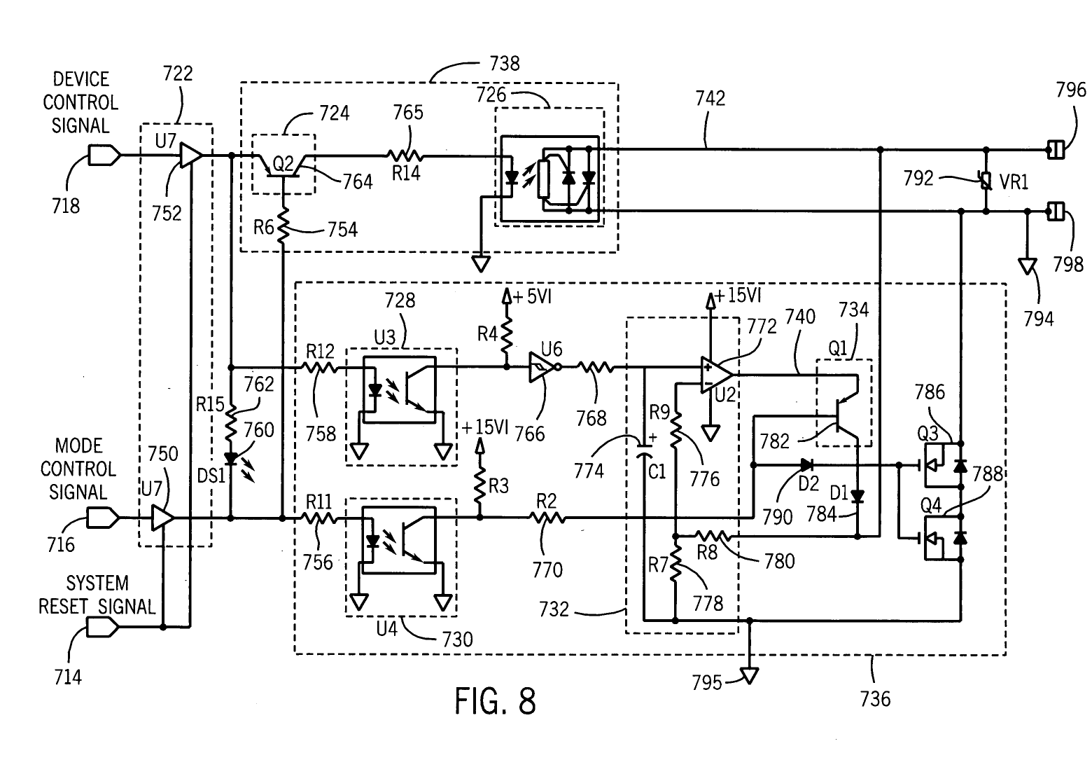

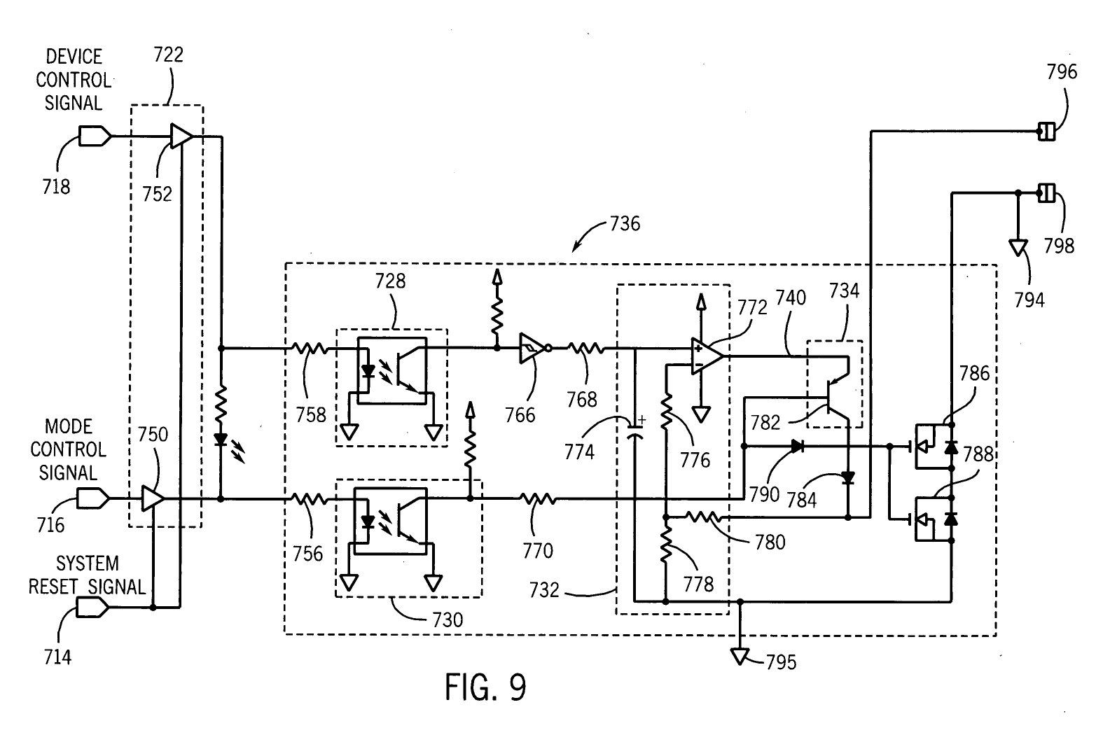

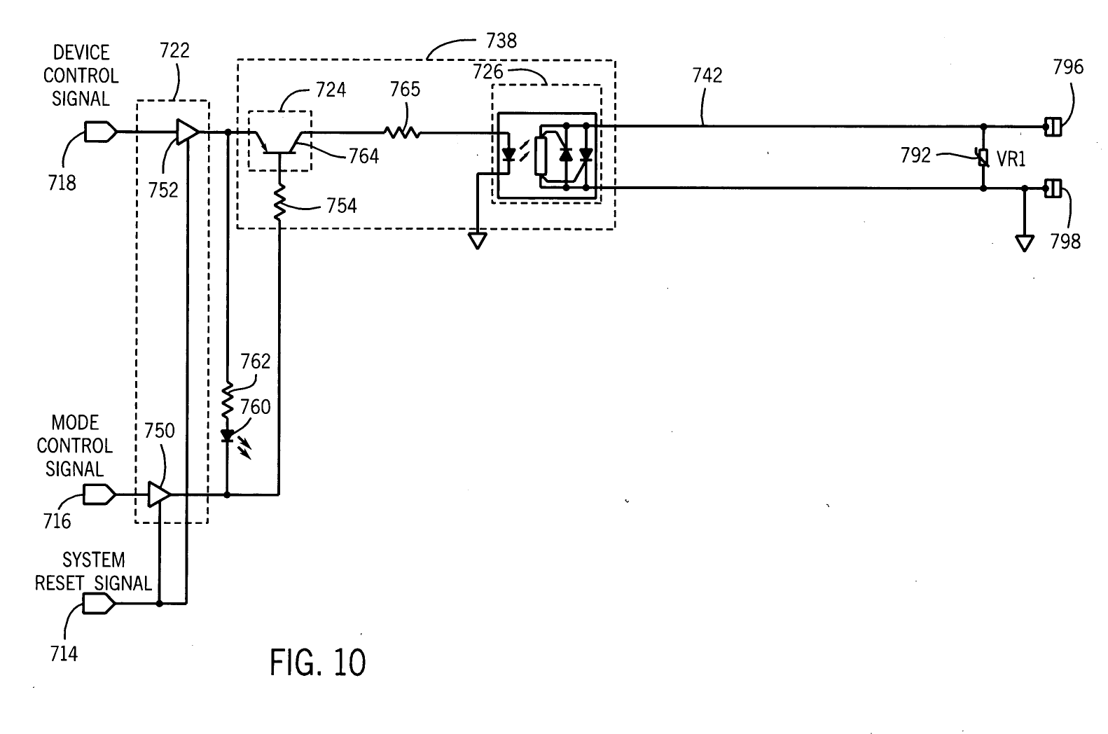

FIG. 8 schematically illustrates a configurable output circuit 720 which is an alternative embodiment of output circuit 420 shown in FIG. 7. Output circuit 720 receives reset signal 714, mode control signal 716, and device control signal 718 as inputs, and includes a buffer 722, a switch 724, an optical switch/relay 726, optical isolators 728 and 730, an integrator 732, and a switch 734. Output circuit 720 is subdivided into an analog output circuit 736 (shown in FIG. 9) and a binary output circuit 738 (shown in FIG. 10). In analog output mode, analog output circuit 736 provides analog output signal 740. In binary output mode, binary output circuit 738 provides binary output signal 742.

Table I below provides exemplary input and output signal ratings for output circuit 720.

| Symbol | Parameter | Value | Units |
|---|---|---|---|
| Device | Pulse Width Modulated (PWM) Device Control Signal | | |
| Control | Maximum frequency | 1200 | Hz |
| | Minimum input signal | 3.15 | V |
| Mode Control | Mode Control Signal | | |
| | Minimum Input High Level | 3.15 | V |
| System | System Reset Signal | | |
| Reset | Maximum Input Low Level | 1.35 | V |
| AO/BO | Analog Output Signal/Binary Output Signal | | |
| | Maximum Output Voltage: analog output, binary output | 10, 36 | V |
| | Maximum Output: analog output, binary output | 10, 500 | mA |
| | Maximum Surge Current (binary output 10us) | 5 | A |
| | Maximum Blocking Voltage (binary output) | 400 | V |
| 15 VI | 15 V Isolated Power Supply | 14.25 to | V |
| | | 15.75 | |
| 5 VI | 5 VI Isolated Power Supply (5 VI isolated power supply | 4.75 to | V |
| | derived from 15 VI using voltage reference) | 5.05 | |
| Power | Maximum Power Dissipation: | | |
| Dissipation | Analog Output | 735 | mW |
| | Binary Output | 1961 | mW |

Table II below provides exemplary component values for output circuit 720.

| Component | | |
|---|---|---|
| Reference | Quantity | Description |
| U1 | 1 | IC, Opto Isolated Solid State Relay, SP646 SCR |
| R11,R12 | 2 | Resister, 680 Ohm, 1%, 1/16 W, 200 PPM |
| C1 | 1 | Elec, 22 UF, 16 V, TR, 20%, −40 + 105 |
| VR1 | 1 | Mov, 68 V, 56 V, 100 A, TR |
| U3,U4 | 2 | Ic Opto Coupler, ISD202 ISOCOM DIP 8 Pins |
| Q1,Q2 | 2 | MMBTA56, Driver, PNP, S3 |
| Q3,Q4 | 2 | FET, FDN5618P, P-Channel |
| U2 | 1 | Ic_Operational Amplifier_Quad_LM2902_SO14 |
| U5 | 1 | IC, Voltage Ref. TL431 |
| U7 | 1 | IC, Digital TnState-Quad Buffer, CMOS, SO14, MC74HC125AD |
| D1,D2,D3 | 3 | Diode, Switching, 100 V, 25 nA, 225 mW, 1N4148, SOT23 |
| R14,R15 | 2 | Resisters, 340 Ohm, 1%, 1/16 W, THK 100 PPM |
| DS1 | 1 | LED_GreenDifused_2.6 mcd @ 20 mA_155_1206 (LED lamp) |
| R1-R8 | 8 | Resisters, 10 K, 1%, 1/16 W, THK 100 PPM |
| R9,R10 | 2 | Resister, 47.5 KOhm, 1%, 1/16 W, 200 PPM |
| R13 | 1 | Resister, 4.99 KOhm, 1%, 1/16 W, 200 PPM |
| U6 | 1 | IC, Digital, 74AHC1G14, Schmitt Trigger Inverter, Single Gate, |
| | | CMOSSMT, 50T23-5 |

Buffer 722 includes buffers 750 and 752. In one embodiment, buffers 750 and 752 are part of a single integrated circuit (IC) package. In another embodiment, buffers 750 and 752 are separate ICs. Buffer 750 receives mode control signal 716 and system reset signal 714 as inputs. Buffer 750 is coupled to switch 724 via resistor 754, and to optical isolator 730 via resistor 756 such that switch 724 and optical isolator 730 receive mode control signal as an input. Buffer 750 receives device control signal 718 and system reset signal 714 as inputs. Buffer 752 is coupled to switch 724, and optical isolator 728 via resistor 758 such that switch 724 and optical isolator 728 receive device control signal 718 as an input.

Switch 724, included in binary output circuit 738, includes transistor 764. The drain of transistor 764 is coupled to buffer 752 such that it receives device control signal 718, while the source of transistor 764 is coupled to optical switch/relay 726 via resistor 765. The gate of transistor 764 is coupled to buffer 750 via resistor 754 such that it receives mode control signal 716.

Optical switch/relay 726, included in binary output circuit 738, is configured to receive device control signal 718 from switch 724 and to provide binary output signal 742 to an output system or device (not shown) coupled to output terminals 796 and 798 in response to device control signal 718. In the illustrated embodiment, optical switch/relay 724 is an optically isolated solid state relay. In this embodiment an optically isolated relay is used in order to isolate device control signal 718 from an AC output device (not shown) coupled to output circuit 720 without the slow speed and short life of the contacts associated with mechanical relays.

Optical isolator 728, included in analog output circuit 736, is coupled to buffer 752 via resistor 758 such that it receives device control signal 718 as an input. Optical isolator 728 is further coupled to integrator 732 via buffer 766 and resistor 768 such that it provides inverted device control signal 718 to integrator 732. Optical isolator 730, included in analog output circuit 736, is coupled to buffer 750 via resistor 756 such that it receives mode control signal 716 as an input. Optical isolator 730 is further coupled to switch 734 via resistor 770 such that it provides mode control signal 716 to switch 734.

Integrator 732, included in analog output circuit 736, includes operational amplifier 772, capacitor 774, and resistors 776, 778, and 780. In the illustrated embodiment, capacitor 774 and resistors 776, 778, and 780 are selected such that integrator 732 has a time constant of about 1.045 seconds. In another embodiment, other values may be selected. Integrator 732 is coupled to optical isolator 728 via inverter 766 and 768 such that it receives inverted device control signal 718 as an input to non-inverting input of operational amplifier 772. Integrator 732 is further coupled to switch 734 and is configured to provide a time averaged version of inverted device control signal 718 to switch 734 in the form of analog output signal 740.

Switch 734, included in analog output circuit 736, includes transistor 782. The drain of transistor 782 is coupled to integrator 732 such that it receives analog output signal 740 from integrator 740. The source of transistor 782 is coupled to output terminal 796 and to integrator 732 via diode 784 such that switch 734 provides analog output signal 740 to an output system or device (not shown) coupled to output terminals 796 and 798, as well as to integrator 732 as a feedback signal. The gate of transistor 782 is coupled to optical isolator 730 via resistor 770 such that it receives mode control signal 716 as an input.

FIG. 9 schematically illustrates a simplified version of output circuit 720 in which the circuit components that are not used in analog output mode have been removed and the components of analog output circuit 736 are shown. Analog output circuit 736 receives mode control signal 716 and device control signal 718 from buffer 722 and includes optical isolators 728 and 730, integrator 732, and switch 734. When output circuit 720 operates in analog output mode, analog output circuit 736 provides analog output signal 740 to an output system or device (not shown) coupled to output terminals 796 and 798.

In the illustrated embodiment, in order to configure output circuit 720 to operate in analog output mode, mode control signal 716 is set to a TTL “high.” Mode control signal 716 is received by optical isolator 730, which couples mode control signal 716 to the gate of transistor 782 via resistor 770. Mode control signal 716 is also coupled to transistors 786 and 788 via diode 790. Transistors 786 and 788 selectively couple AC return 794 to isolated ground 795 in response to mode control signal 716. When mode control signal 716 is a TTL “high,” transistors 782, 786, and 788 are “ON.” Accordingly, AC return 794 is coupled to isolated ground 795 and switch 734 provides analog output signal 740 to an output system or device (not shown) coupled to output terminals 796 and 798.

Device control signal 718 is a time-optimized PWM signal that is used to generate analog output signal 740. When output circuit 720 is configured to operate in analog output mode, device control signal 718 is received by optical isolator 728. Optical isolator 728 couples device control signal 718 to integrator 732 via inverter 766 and resistor 768. Integrator 732 then provides analog output signal 740 to switch 734, which provides analog output signal 740 to an output system or device (not shown) coupled to output terminals 796 and 798.

FIG. 10 schematically illustrates a simplified version of output circuit 720 in which the circuit components that are not used in binary output mode have been removed and the components of binary output circuit 738 are shown. Binary output circuit 738 receives mode control signal 716 and device control signal 718 from buffer 722 and includes switch 724 and optical switch/relay 726. When output circuit 720 operates in binary output mode, binary output circuit 738 provides binary output signal 742 to an output system or device (not shown) coupled to output terminals 796 and 798. In binary mode, the pulse width modulated signal (PWM) is used to close the normally open solid state relay U1.

In order to configure output circuit 720 to operate in binary output mode, mode control signal 716 is set to a TTL “low.” Device control signal 718 is a PWM signal and is coupled to the drain of transistor 764. Switch 724 is “ON” and accordingly couples device control signal 718 to optical switch/relay 726 via resistor 765 such that the normally open solid state relay is opened and closed according to device control signal 718 to provide binary output signal 742 to an output system or device (not shown) coupled to output terminals 796 and 798.

In the illustrated embodiment, binary output circuit also includes light emitting diode (LED) 760 and resistor 762. LED 760 and resistor 762 are connected in series between the output of buffer 750 and the output of buffer 752. When mode control signal 716 is a TTL “low” and output circuit 720 is operating in binary mode, LED 720 is ON whenever device control signal 718 is a TTL “high.” LED 760 is preferably bright enough to be seen in a ceiling or remote mounting location.

According to the illustrated embodiment, analog output circuit 736 and binary output circuit 738 share output terminals 796 and 798. Analog output circuit 736 is protected from high voltage spikes when output circuit 720 is configured to operate in binary output mode by voltage regulating device 792. Further, the connection between AC return 794 and isolated digital ground 795 is broken via transistors 786 and 788 when the device is in binary output mode.

In typical applications and installations (e.g., an electrical device in a controlled system), electrical devices using output device 10 are installed (e.g., mounting and wiring of the electrical device(s)) and configured (e.g., initiation, powering-up, programming, testing, etc.) by different persons (e.g., having different expertise and/or negotiated responsibilities). For example, in a new construction installation, a first person (such as an electrician) mounts or installs the device and connects the wiring. Thereafter, a second person (such as a building, systems, or HVAC engineer) can program, reprogram, initiate, power-up or otherwise have operational control over HVAC system.

The device with the configurable output may be a general device configured for a variety of applications and systems, which would have an unknown input characteristic (e.g., analog or binary). This general device may be configured according to the application. Alternatively, while the system is being configured, tested, and/or powered-up, it may become desirable to add an additional controlled device. If necessary, the configurable output can be configured to be compatible with this additional controlled device. Alternatively, after the installation and initial configuration, it may become desirable to modify or expand the controlled system. Such modification may require a different output. An engineer or other technician can configure the output accordingly.

It is also important to note that the construction and arrangement of the elements of the configurable output as shown in the preferred and other exemplary embodiments are illustrative only. Although only a few embodiments of the present invention have been described in detail in this disclosure, those skilled in the art who review this disclosure will readily appreciate that many modifications are possible (e.g., variations in sizes, dimensions, structures, shapes and proportions of the various elements, values of parameters, mounting arrangements, materials, colors, orientations, etc.) without materially departing from the novel teachings and advantages of the subject matter recited in the claims. For example, the configurable output circuit 10 may be used in many different types of devices and packages. As such, the environmental characteristics are defined and adaptable on a device-by-device basis. Accordingly, all such modifications are intended to be included within the scope of the present invention as defined in the appended claims. The order or sequence of any process or method steps may be varied or re-sequenced according to alternative embodiments. In the claims, any means-plus-function clause is intended to cover the structures described herein as performing the recited function and not only structural equivalents but also equivalent structures. Other substitutions, modifications, changes and/or omissions may be made in the design, operating conditions and arrangement of the preferred and other exemplary embodiments without departing from the spirit of the present invention as expressed in the appended claims.

1. A configurable output circuit capable of producing an output signal to control an output device, the output circuit comprising:
an analog output circuit capable of producing an analog output signal usable to control the output device;
a binary output circuit capable of producing a binary output signal usable to control the output device; and
means for configuring the output circuit to provide an analog output mode or a binary output mode so that the output signal is either the binary output signal or the analog output signal.

2. The output circuit of claim 1 wherein the means for configuring the output signal comprises at least one switch coupled to the analog output circuit and the binary output circuit.

3. The output circuit of claim 2 wherein the switch is configured to deactivate either the analog output circuit or the binary output circuit.

4. The output circuit of claim 3 wherein the switch is an opto coupler.

5. The output circuit of claim 1 wherein the binary output circuit includes an optically isolated solid state relay.

6. The output circuit of claim 1 further comprising a first input and a second input, wherein the first input receives an output device control signal and the second input receives a mode control signal.

7. The output circuit of claim 6 wherein the output device signal is converted to one of the binary output signal or the analog output signal.

8. The output circuit of claim 6 wherein the output device signal is a pulse width modulated signal.

9. The output circuit of claim 6 wherein the mode control signal is provided by a computing device coupled to the output circuit.

10. The output circuit of claim 9 wherein the computing device is temporally coupled to the output circuit.

11. The output circuit of claim 6 further comprising a third input that receives a reset signal configured to set the output device control signal and the mode control signal to known states.

12. A system comprising:
a controller;
an output device; and
an output circuit configurable in:
an analog output mode, wherein an analog output circuit portion of the output circuit is capable of producing an analog output signal usable to control the output device; and
a binary output mode, wherein a binary output circuit portion of the output circuit is capable of producing a binary output signal usable to control the output device;
wherein either the analog output signal or the binary output signal is provided as an output signal to the output device.

13. The system of claim 12 further comprising a switch configured to deactivate either the analog output circuit or the binary output circuit.

14. The output circuit of claim 12 wherein the binary output circuit includes an optically isolated solid state relay.

15. The output circuit of claim 12 further comprising a first input and a second input, wherein the first input receives an output device control signal and the second input receives a mode control signal.

16. The output circuit of claim 15 wherein the output device signal is converted to one of the binary output signal or the analog output signal.

17. The output circuit of claim 15 wherein the output device signal is a pulse width modulated signal.

18. The output circuit of claim 15 wherein the mode control signal is provided by a computing device coupled to the output circuit.

19. The output circuit of claim 15 further comprising a third input that receives a reset signal configured to set the output device control signal and the mode control signal to known states.

20. The output circuit of claim 12 wherein the output device is a component of a Heating, Ventilation, and Air-Conditioning (HVAC) system.

21. A configurable output circuit capable of producing an output signal comprising:
a first input configured to receive a first input signal;
a first output circuit being capable of producing an analog output signal based on the first input signal and usable to control an output device;
a second output circuit being capable of producing a binary output signal based on the first input signal and usable to control the output device;
a second input configured to receive a second input signal; and
a switch being capable of switching the output signal between a first mode of operation in which the first output circuit is active and the output signal is the analog output signal to a second mode of operation in which the second output circuit is active and the output signal is the binary output signal, the switch switching the configurable output circuit between the first mode of operation and the second mode of operation responsive to the second input signal.

22. The output circuit of claim 21 wherein the second input signal is provided by a computing device.

23. The output circuit of claim 22 wherein the computing device is a computer.

24. The output circuit of claim 22 wherein the computing device is a Personal Digital Assistant (PDA).

25. The output circuit of claim 21 wherein the first input signal comprises an output control device.

26. The output circuit of claim 25 wherein the output control device is a pulse width modulated signal.

27. The output circuit of claim 21 wherein the second signal is a mode control signal.

28. The output circuit of claim 21 further comprising a third input that receives a reset signal configured to set the first signal and the second signal to known states.

29. A method of providing an output control signal to an output device, the method comprising:
providing an output circuit having a binary output circuit capable of producing a binary signal, and an analog output circuit capable of producing an analog signal;
receiving a first output mode control signal;
configuring the output circuit in either a binary output mode or an analog output mode;
receiving a first device control signal;
providing the output control signal to the output device as either the binary signal or the analog signal.

30. The method of claim 29 further comprising receiving a reset signal configured to set the first signal and the second signal to known states.

31. The method of claim 29 wherein the output control signal is for controlling a component of a Heating, Ventilation, and Air-Conditioning (HVAC) system.

32. The method of claim 29 further comprising:
receiving a second output mode control signal;
configuring the output circuit in the other of the binary output mode or the analog output mode'
receiving a second device control signal; and
providing the output control signal to the output device as the other of the binary signal or the analog signal.
